(19) United States
(12) Patent Application Publication
(10) Pub. No.: US 2019/0241694 A1
(43) Pub. Date: Aug. 8, 2019

(54) CURABLE COMPOSITION FOR FORMING ELASTIC RESIN LAYER

(71) Applicant: HITACHI CHEMICAL COMPANY, LTD., Chiyoda-ku, Tokyo (JP)

(72) Inventors: Tomoaki SHIBATA, Chiyoda-ku, Tokyo (JP); Satoshi UEHARA, Chiyoda-ku, Tokyo (JP); Aya IKEDA, Chiyoda-ku, Tokyo (JP); Shunsuke OTAKE, Chiyoda-ku, Tokyo (JP); Tomonori MINEGISHI, Chiyoda-ku, Tokyo (JP); Kazuyoshi TENDOU, Chiyoda-ku, Tokyo (JP)

(73) Assignee: HITACHI CHEMICAL COMPANY, LTD., Chiyoda-ku, Tokyo (JP)

(21) Appl. No.: 16/344,493

(22) PCT Filed: Oct. 25, 2017
(86) PCT No.: PCT/JP2017/038518

§ 371 Date: Apr. 24, 2019

(30) Foreign Application Priority Data
Oct. 28, 2016 (JP) 2016-211837

(51) Int. Cl. C08F 287/00; C08F 220/18; C08F 212/08; C08F 2/48; C08F 236/02; C08F 2/44; C08J 5/18; C08L 53/02

(52) U.S. Cl. CPC C08F 287/00; C08F 220/18; C08F 212/08; C08F 2/48; H01L 21/56; C08F 2/44; C08J 5/18; C08L 53/025; C08F 236/02

(57) ABSTRACT

Disclosed is a curable composition for forming a stretchable resin layer, containing: (A) an elastomer having a polystyrene chain; (B) monofunctional straight-chain alkyl (meth)acrylate; (C) monofunctional (meth)acrylate having an alicyclic group; (D) a difunctional or higher compound having two or more ethylenically unsaturated groups; and (E) a polymerization initiator.

### TECHNICAL FIELD

The present invention relates to a curable composition for forming a stretchable resin layer, and a semiconductor device including a stretchable resin layer.

### BACKGROUND ART

A demand for wearable appliances has increased recently. The wearable appliances have been required to have flexibility and stretchability for easy attachment on a curved surface of the body and for suppression of bad connection due to desorption, in addition to a reduction in the size. A member required to have flexibility and stretchability, in general, can be formed of liquid silicone or liquid polyurethane.

Patent Literature 1 discloses a resin composition for forming a flexible resin layer, containing a styrene-based elastomer.

Patent Literature 2 discloses a heat-resistant moisture-proof insulating coating material containing copolymer rubber having a block of a polystyrene chain. Patent Literature 3 discloses a photocurable resin composition containing a urethane compound having an ethylenically unsaturated double bond, and a photopolymerizable monomer having a cyclic aliphatic group.

### CITATION LIST

### Patent Literature

Patent Literature 1: WO2016/080346

Patent Literature 2: JP2005-162986A

Patent Literature 3: JP2007-308681A

### SUMMARY OF INVENTION

### Technical Problem

For example, it is desirable that a sealing resin layer sealing a semiconductor element to be mounted on the wearable appliances, has high stretchability. In addition, a stretchable resin layer having sufficient adhesiveness to a stretchable base material such as a flexible base material configuring the wearable appliances or the like, is also required.

Therefore, an object of one aspect of the present invention is to provide a curable composition capable of fonning a stretchable resin layer having sufficient stretchability and adhesiveness.

### Solution to Problem

One aspect of the present invention provides a curable composition for forming a stretchable resin layer, containing: (A) an elastomer having a polystyrene chain; (B) monofunctional straight-chain alkyl (meth)acrylate; (C) monofunctional (meth)acrylate having an alicyclic group; (D) a Bifunctional or higher compound having two or more ethylenically unsaturated groups; and (E) a polymerization initiator. In other words, one aspect of the present invention relates to application or use for manufacturing a stretchable resin layer of the curable composition described above.

As result of intensive studies of the present inventors, it has been found that a curable composition containing a combination of specific components described above, is capable of forming a stretchable resin layer having sufficient stretchability and adhesiveness.

### Advantageous Effects of Invention

The curable composition according to one aspect of the present invention, is capable of forming a stretchable resin layer having sufficient stretchability and adhesiveness.

### BRIEF DESCRIPTION OF DRAWINGS

FIG. 1 is a stress-strain curve illustrating a measurement example of a stretch recovery rate.

FIG. 2 is a sectional view illustrating an embodiment of a semiconductor device.

FIG. 3 is a sectional view illustrating an embodiment of a flexible substrate and a circuit component.

FIG. 4 is a sectional view illustrating an embodiment of a step of obtaining a plurality of semiconductor devices.

### DESCRIPTION OF EMBODIMENTS

Hereinafter, several embodiments of the present invention will be described in detail. However, the present invention is not limited to the following embodiments.

Curable Composition

A curable composition according to an embodiment, contains: (A) an elastomer having a polystyrene chain; (B) monofunctional straight-chain alkyl (meth)acrylate; (C) monofunctional (meth)acrylate having an alicyclic group; (D) a difunctional or higher compound having two or more ethylenically unsaturated groups; and (E) a polymerization initiator. The curable composition is capable of forming a cured material or a cured film having stretchability, by being cured with irradiation of an active light ray or heating.

Herein, the “stretchability” indicates properties capable of recovering to the original shape or a shape close to the original shape when released from a load after strain occurs due to a tensile load. For example, it can be said that a material capable of recovering to the original shape or a shape close to the original shape, after strain of 50% occurs due to a tensile load, has stretchability. More specifically, it can be said that a resin layer of which a stretch recovery rate described below is greater than or equal to 80%, is a stretchable resin layer.

(A) Elastomer

An elastomer having a polystyrene chain (hereinafter, also referred to as a “styrene-based elastomer”), for example, can be a copolymer having a polystyrene chain as a hard segment, a polydiene chain (for example, a polybutadiene chain and a polyisoprene chain) as a soft segment. Examples of a commercially available product of such a styrene-based elastomer, include “DYNARON SEBS Series” manufactured by JSR Corporation, “Kraton D polymer Series” manufactured by KRATON CORPORATION, and “AR Series” manufactured by ARONKASEI CO., LTD.

A double bond of the polydiene chain of the styrene-based elastomer may be saturated by being hydrogenated. A styrene-based elastomer having a hydrogenated polybutadiene chain, can be a styrene-ethylene/butylene-styrene block copolymer (a hydrogenated styrene butadiene copolymer). A styrene-based elastomer having a hydrogenated polyisoprene chain, can be a styrene-ethylene/propylene-styrene block copolymer (a hydrogenated styrene isoprene copolymer). It is considered that a styrene-based elastomer having a hydrogenated polydiene chain, contributes to improvement in weather resistance. Examples of a commercially available product of the styrene-based elastomer having a hydrogenated polydiene chain, include “DYNARON HSBR Series” manufactured by JSR Corporation, “Kraton G polymer Series” manufactured by KRATON CORPORATION, “Tuftec Series” manufactured by Asahi Kasei Corp., and “SEPTON Series” manufactured by KURARAY CO., LTD.

The weight average molecular weight of the styrene-based elastomer may be 30000 to 200000, or 50000 to 150000, from the viewpoint of coating properties of the curable composition. Here, the weight average molecular weight (Mw) indicates a value in terms of standard polysterene, obtained by a gel permeation chromatography (GPC).

The content of the styrene-based elastomer of the component of (A), may be 10 mass % to 50 mass %, or 20 mass % to 40 mass %, with respect to the total amount of the component of (A), the component of (B), the component of (C), and the component of (D). In a case where the content of the styrene-based elastomer is greater than or equal to 10 mass %, the stretchability tends to be easily improved. In a case where the content of the styrene-based elastomer is less than or equal to 50 mass %, the viscosity of the curable composition is low, and thus, coating properties tend to be improved.

(B) Monofunctional Straight-Chain Alkyl (Meth)Acrylate

The monofunctional straight-chain alkyl (meth)acrylate is an ester compound having one (meth)acryloyl group and one straight-chain alkyl group. In general, the monofunctional straight-chain alkyl (meth)acrylate is an ester compound formed of a (meth)acrylic acid and straight-chain alkyl alcohol. The number of carbon atoms of the straight-chain alkyl group of the straight-chain alkyl (meth)acrylate, may be less than or equal to 12, or may be less than or equal to 10. In a case where the number of carbon atoms is less than or equal to 12, the cured material formed of the curable composition tends to be hardly clouded, in particular, when an elastomer having a hydrogenated polydiene chain is used. The number of carbon atoms of the straight-chain alkyl group, may be greater than or equal to 6, or may be greater than or equal to 8.

Examples of the monofunctional straight-chain alkyl (meth)acrylate, include isooctyl (meth)acrylate, isodecyl (meth)acrylate, lauryl (meth)acrylate, isostearyl acrylate, stearyl acrylate, and tridecyl acrylate. Among them, one kind or more compounds having a straight-chain alkyl group of which the number of carbon atoms is less than or equal to 12, may be selected from isooctyl (meth)acrylate, isodecyl (meth)acrylate, and lauryl (meth)acrylate. Only one kind of such compounds or a combination of two or more kinds thereof can be used, and such compounds can be combined with other monofunctional straight-chain alkyl (meth)acrylates.

The content of the monofunctional straight-chain alkyl (meth)acrylate of the component (B), may be 10 mass % to 50 mass %, or may be 20 mass % to 40 mass %, with respect to the total amount of the component (A), the component (B), the component (C), and the component (D). In a case where the content of the component of (B) is greater than or equal to 10 mass %, the effect of improving the stretchability tends to be relatively improved. In a case where the content of the component of (B) is less than or equal to 50 mass %, the effect of improving the adhesiveness tends to be relatively improved.

(C) Monofunctional (Meth)Acrylate Having Alicyclic Group

The monofunctional (meth)acrylate having an alicyclic group, in general, is an ester compound formed of a (meth)acrylic acid, and an alcohol compound having an alicyclic group. The monofunctional (meth)acrylate having an alicyclic group, for example, can be one kind or more compounds selected from cyclohexyl acrylate, 3,3,5-trimethylcyclohexanol (meth)acrylate, 4-tert-butylcyclohexanol (meth)acrylate, isobornyl acrylate, dicyclopentanyl acrylate (tricyclodecyl acrylate), and tetrahydrofurfuryl acrylate. Only one kind of such compounds or a combination of two or more kinds thereof can be used, and such compounds can be combined with other monofunctional (meth)acrylates having an alicyclic group.

The content of the monofunctional (meth)acrylate having an alicyclic group of the component of (C), may be 10 mass % to 50 mass %, or may be 20 mass % to 40 mass %, with respect to the total amount of the component (A), the component (B), the component (C), and the component (D). In a case where the content of the component of (C) is greater than or equal to 10 mass %, the effect of improving the adhesiveness tends to be relatively improved. In a case where the content of the component of (C) is less than or equal to 50 mass %, the effect of improving the stretchability tends to be relatively improved.

(D) Difunctional or Higher Compound Having Two or More Ethylenically Unsaturated Groups

The ethylenically unsaturated group of the difunctional or higher compound having two or more ethylenically unsaturated groups, for example, may be a (meth)acryloyl group, a vinyl group, or a combination thereof. Examples of the difunctional or higher compound having two or more ethylenically unsaturated groups, include (meth)acrylate, halogenated vinylidene, vinyl ether, vinyl ester, vinyl pyridine, vinyl amide, and arylated vinyl. Among them, at least one of (meth)acrylate or arylated vinyl may be selected, from the viewpoint of the transparency of the stretchable resin layer.

Examples of difunctional (meth)acrylate having two (meth)acryloyl groups, include aliphatic (meth)acrylate such as ethylene glycol di(meth)acrylate, diethylene glycol di(meth)acrylate, triethylene glycol di(meth)acrylate, tetraethylene glycol di(meth)acrylate, polyethylene glycol di(meth)acrylate, propylene glycol di(meth)acrylate, dipropylene glycol di(meth)acrylate, tripropylene glycol di(meth)acrylate, tetrapropylene glycol di(meth)acrylate, polypropylene glycol di(meth)acrylate, ethoxylated polypropylene glycol di(meth)acrylate, 1,3-butanediol di(meth)acrylate, 1,4-butanediol di(meth)acrylate, neopentyl glycol di(meth)acrylate, 3-methyl-1,5-pentanediol di(meth)acrylate, 1,6-hexanediol di(meth)acrylate, 2-butyl-2-ethyl-1,3-propanediol di(meth)acrylate, 1,9-nonanediol di(meth)acrylate, 1,10-decanediol di(meth)acrylate, glycerin di(meth)acrylate, tricyclodecane dimethanol di(meth)acrylate, and ethoxylated 2-methyl-1,3-propanediol di(meth)acrylate; alicyclic (meth)acrylate such as cyclohexane dimethanol di(meth)acrylate, ethoxylated cyclohexane dimethanol di(meth)acrylate, propoxylated cyclohexane dimethanol di(meth)acrylate, ethoxylated propoxylated cyclohexane dimethanol di(meth)acrylate, tricyclodecane dimethanol di(meth)acrylate, ethoxylated tricyclodecane dimethanol di(meth)acrylate, propoxylated tricyclodecane dimethanol di(meth)acrylate, ethoxylated propoxylated tricyclodecane dimethanol di(meth)acrylate, ethoxylated hydrogenated bisphenol A di(meth)acrylate, propoxylated hydrogenated bisphenol A di(meth)acrylate, ethoxylated propoxylated hydrogenated bisphenol A di(meth)acrylate, ethoxylated hydrogenated bisphenol F di(meth)acrylate, propoxylated hydrogenated bisphenol F di(meth)acrylate, and ethoxylated propoxylated hydrogenated bisphenol F di(meth)acrylate; aromatic (meth)acrylate such as ethoxylated bisphenol A di(meth)acrylate, propoxylated bisphenol A di(meth)acrylate, ethoxylated propoxylated bisphenol A di(meth)acrylate, ethoxylated bisphenol F di(meth)acrylate, propoxylated bisphenol F di(meth)acrylate, ethoxylated propoxylated bisphenol F di(meth)acrylate, ethoxylated bisphenol AF di(meth)acrylate, propoxylated bisphenol AF di(meth)acrylate, ethoxylated propoxylated bisphenol AF di(meth)acrylate, ethoxylated fluorene type di(meth)acrylate, propoxylated fluorene type di(meth)acrylate, and ethoxylated propoxylated fluorene type di(meth)acrylate; heterocyclic (meth)acrylate such as ethoxylated isocyanurate di(meth)acrylate, propoxylated isocyanurate di(meth)acrylate, and ethoxylated propoxylated isocyanurate di(meth)acrylate; a caprolactone modified product thereof; aliphatic epoxy (meth)acrylate such as neopentyl glycol type epoxy (meth)acrylate; alicyclic epoxy (meth)acrylate such as cyclohexane dimethanol type epoxy (meth)acrylate, hydrogenated bisphenol A type epoxy (meth)acrylate, and hydrogenated bisphenol F type epoxy (meth)acrylate; and aromatic epoxy (meth)acrylate such as resorcinol type epoxy (meth)acrylate, bisphenol A type epoxy (meth)acrylate, bisphenol F type epoxy (meth)acrylate, bisphenol AF type epoxy (meth)acrylate, and fluorene type epoxy (meth)acrylate.

Examples of trifunctional or higher polyfunctional (meth)acrylate having three or more (meth)acryloyl groups, include aliphatic (meth)acrylate such as trimethylolpropane tri(meth)acrylate, ethoxylated trimethylolpropane tri(meth)acrylate, propoxylated trimethylolpropane tri(meth)acrylate, ethoxylated propoxylated trimethylolpropane tri(meth)acrylate, pentaerythritol tri(meth)acrylate, ethoxylated pentaerythritol tri(meth)acrylate, propoxylated pentaerythritol tri(meth)acrylate, ethoxylated propoxylated pentaerythritol tri(meth)acrylate, pentaerythritol tetra(meth)acrylate, ethoxylated pentaerythritol tetra(meth)acrylate, propoxylated pentaerythritol tetra(meth)acrylate, ethoxylated propoxylated pentaerythritol tetra(meth)acrylate, ditrimethylol propane tetraacrylate, and dipentaerythritol hexa(meth)acrylate; heterocyclic (meth)acrylate such as ethoxylated isocyanurate tri(meth)acrylate, propoxylated isocyanurate tri(meth)acrylate, and ethoxylated propoxylated isocyanurate tri(meth)acrylate; a caprolactone modified product thereof; and aromatic epoxy (meth)acrylate such as phenol novolac type epoxy (meth)acrylate and cresol novolac type epoxy (meth)acrylate.

The component of (D) may be a compound having an alicyclic group, from the viewpoint of compatibility with respect to the styrene-based elastomer, transparency, heat resistance, and adhesiveness with respect to polyimide and a copper foil, and examples thereof include cyclohexane dimethanol di(meth)acrylate and tricyclodecane dimethanol di(meth)acrylate.

Only one kind of the compounds exemplified above or a combination of two or more kinds thereof can be used, and the selected compounds can be combined with other difunctional or higher compounds.

The content of the difunctional or higher compound of the component of (D), may be 0.3 mass % to 20 mass %, may be 0.5 mass % to 10 mass %, or may be 1 mass % to 5 mass %, with respect to the total amount of the component (A), the component (B), the component (C), and the component (D). In a case where the content of the component of (D) is greater than or equal to 0.3 mass %, tackiness tends to be reduced after curing, and the effect of improving the stretchability tends to be relatively improved. In a case where the content of the component of (D) is less than or equal to 20 mass %, the effect of improving the stretchability tends to be relatively improved.

(E) Polymerization Initiator

The polymerization initiator is a compound of starting polymerization by heating or irradiation of an ultraviolet ray or the like, and for example, can be a thermal radical polymerization initiator or a photoradical polymerization initiator. The photoradical polymerization initiator may be selected since the photoradical polymerization initiator has a high curing rate, and can be cured at a normal temperature.

Examples of the thermal radical polymerization initiator include ketone peroxide such as methyl ethyl ketone peroxide, cyclohexanone peroxide, and methyl cyclohexanone peroxide; peroxyketal such as 1,1-bis(t-butylperoxy)cyclohexane, 1,1-bis(t-butylperoxy)-2-methylcyclohexane, 1,1-bis(t-butylperoxy)-3,3,5-trimethylcyclohexane, 1,1-bis(t-hexylperoxy)cyclohexane, and 1,1-bis(t-hexylperoxy)-3,3,5-trimethylcyclohexane; hydroperoxide such as p-menthane hydroperoxide; dialkyl peroxide such as α,α′-bis(t-butylperoxy)diisopropylbenzene, dicumyl peroxide, t-butyl cumyl peroxide, and di-t-butyl peroxide; diacyl peroxide such as octanonyl peroxide, lauroyl peroxide, stearyl peroxide, and benzoyl peroxide; peroxycarbonate such as bis(4-t-butylcyclohexyl) peroxydicarbonate, di-2-ethoxy ethyl peroxydicarbonate, di-2-ethyl hexyl peroxydicarbonate, and di-3-methoxy butyl peroxycarbonate; peroxyester such as t-butyl peroxypivalate, t-hexyl peroxypivalate, 1,1,3,3-tetramethyl butyl peroxy-2-ethyl hexanoate, 2,5-dimethyl-2,5-bis(2-ethyl hexanonyl peroxy) hexane, t-hexyl peroxy-2-ethyl hexanoate, t-butyl peroxy-2-ethyl hexanoate, t-butyl peroxyisobutyrate, t-hexyl peroxyisopropyl monocarbonate, t-butyl peroxy-3,5,5-trimethyl hexanoate, t-butyl peroxylaurylate, t-butyl peroxyisopropyl monocarbonate, t-butyl peroxy-2-ethyl hexyl monocarbonate, t-butyl peroxybenzoate, t-hexyl peroxybenzoate, 2,5-dimethyl-2,5-bis(benzoyl peroxy) hexane, and t-butyl peroxyacetate; and an azo compound such as 2,2′-azobisisobutyronitrile, 2,2′-azobis(2,4-dimethyl valeronitrile), and 2,2′-azobis(4-methoxy-T-dimethyl valeronitrile). The thermal radical polymerization initiator may be the diacyl peroxide, the peroxyester, the azo compound, or a combination thereof, from the viewpoint of curing properties, transparency, and heat resistance.

Examples of the photoradical polymerization initiator include benzoin ketal such as 2,2-dimethoxy-1,2-diphenyl ethan-1-one; α-hydroxy ketone such as 1-hydroxy cyclohexyl phenyl ketone, 2-hydroxy-2-methyl-1-phenyl propan-1-one, and 1-[4-(2-hydroxy ethoxy) phenyl]-2-hydroxy-2-methyl-1-propan-1-one; α-aminoketone such as 2-benzyl-2-dimethyl amino-1-(4-morpholinophenyl)-butan-1-one and 1,2-methyl-1-[4-(methyl thio)phenyl]-2-morpholinopropan-1-one; oxime ester such as 1-[(4-phenyl thio)phenyl]-1,2-octadione-2-(benzoyl) oxime; phosphine oxide such as bis(2,4,6-trimethyl benzoyl) phenyl phosphine oxide, bis(2,6-dimethoxy benzoyl)-2,4,4-trimethyl pentyl phosphine oxide, and 2,4,6-trimethyl benzoyl diphenyl phosphine oxide; a 2,4,5-triaryl imidazole dimer such as a 2-(o-chlorophenyl)-4,5-diphenyl imidazole dimer, a 2-(o-chlorophenyl)-4,5-di(methoxy phenyl) imidazole dimer, a 2-(o-fluorophenyl)-4,5-diphenyl imidazole dimer, a 2-(o-methoxy phenyl)-4,5-diphenyl imidazole dimer, and a 2-(p-methoxy phenyl)-4,5-diphenyl imidazole dimer; a benzophenone compound such as benzophenone, N,N,N′,N′-tetramethyl-4,4′-diaminobenzophenone, N,N,N,N-tetraethyl-4,4′-diaminobenzophenone, and 4-methoxy-4′-dimethyl aminobenzophenone; a quinone compound such as 2-ethyl anthraquinone, phenanthrene quinone, 2-tert-butyl anthraquinone, octamethyl anthraquinone, 1,2-benzanthraquinone, 2,3-benzanthraquinone, 2-phenyl anthraquinone, 2,3-diphenyl anthraquinone, 1-chloroanthraquinone, 2-methyl anthraquinone, 1,4-naphthoquinone, 9,10-phenanthraquinone, 2-methyl-1,4-naphthoquinone, and 2,3-dimethyl anthraquinone; benzoin ether such as benzoin methyl ether, benzoin ethyl ether, and benzoin phenyl ether; a benzoin compound such as benzoin, methyl benzoin, and ethyl benzoin; a benzyl compound such as benzyl dimethyl ketal; an acridine compound such as 9-phenyl acridine and 1,7-bis(9,9′-acridinyl heptane); N-phenyl glycine; and coumarin.

In the 2,4,5-triaryl imidazole dimer, the same and symmetric compounds may be applied, or different and asymmetric compounds may be applied, as a substituent of an aryl group in two triaryl imidazole portions. As with a combination of diethyl thioxanthone and dimethyl aminobenzoate, a thioxanthone compound may be combined with tertiary amine.

The photoradical polymerization initiator may be the α-hydroxy ketone, the phosphine oxide, or a combination thereof, from the viewpoint of the curing properties, the transparency, and the heat resistance. Only one kind of such thermal and photoradical polymerization initiators or a combination of two or more kinds thereof can be used. Such thermal and photoradical polymerization initiators may be combined with a suitable sensitizer.

The content of the polymerization initiator of the component of (E), may be 0.1 part by mass to 10 parts by mass, may be 0.3 part by mass to 7 parts by mass, or may be 0.5 part by mass to 5 parts by mass, with respect to the total amount 100 parts by mass of the component of (A), the component of (B), the component of (C), and the component of (D). In a case where the content of the component of (E) is greater than or equal to 0.1 part by mass, the curing tends to sufficiently progress. In a case where the content of the component of (E) is less than or equal to 10 parts by mass, light transmittance tends to be improved.

A liquid or solid curable composition may be used as it is, or may be used as a resin varnish by diluting the curable composition with an organic solvent. A solventless curable composition that is liquid at a room temperature (25° C.), is advantageous in that an organic solvent is not discharged, the curable composition can be easily applied onto a local portion, and the like.

The organic solvent can be selected from organic solvents capable of dissolving each component of the curable composition. Examples of the organic solvent include aromatic hydrocarbon such as toluene, xylene, mesitylene, cumene, and p-cymene; cyclic ether such as tetrahydrofuran and 1,4-dioxane; ketone such as acetone, methyl ethyl ketone, methyl isobutyl ketone, cyclohexanone, and 4-hydroxy-4-methyl-2-pentanone; ester such as methyl acetate, ethyl acetate, butyl acetate, methyl lactate, ethyl lactate, and γ-butyrolactone; carbonate ester such as ethylene carbonate and propylene carbonate; and amide such as N,N-dimethyl formamide, N,N-dimethyl acetamide, and N-methyl-2-pyrrolidone. The organic solvent may be toluene, N,N-dimethyl acetamide, or a combination thereof, from the viewpoint of solubility and a boiling point. Only one type of such organic solvents or a combination of two or more types thereof can be used.

The curable composition, as necessary, may further contain other components, in addition to the components described above. Examples of the other components include an additive such as an antioxidant, an anti-yellowing agent, a ultraviolet ray absorbent, a visible light absorbent, a coloring agent, a plasticizer, a stabilizer, and a filler. The total content of the component of (A), the component of (B), the component of (C), and the component of (D), for example, may be greater than or equal to 85 mass %, may be greater than or equal to 90 mass %, or may be greater than or equal to 95 mass %, with respect to the total amount of the components other than the organic solvent, in the curable composition.

Cured Material (Stretchable Resin Layer)

An elastic modulus of the cured material (the stretchable resin layer) formed from the curable composition, may be greater than or equal to 0.1 MPa and less than or equal to 100 MPa, may be greater than or equal to 0.2 MPa and less than or equal to 50 MPa, or may be greater than or equal to 0.3 MPa and less than or equal to 30 MPa. In a case where the elastic modulus of the cured material is greater than or equal to 0.1 MPa, a problem that the cured materials are pasted to each other by blocking, tends to hardly occur. In a case where the elastic modulus of the cured material is less than or equal to 100 MPa, the effect of improving the flexibility and the stretchability can be relatively improved.

An elongation at break according to a tensile test of the cured material (the stretchable resin layer) formed of the curable composition, may be greater than or equal to 100%. In a case where the elongation at break of the cured material is greater than or equal to 100%, more excellent stretchability can be obtained. From the same viewpoint, the elongation at break of the cured material may be greater than or equal to 150%, or may be greater than or equal to 200%.

The cured material (the stretchable resin layer) formed from the curable composition, is capable of having high stretchability. The stretchability can be evaluated by using stretch recovery properties to be measured by the following method including two times of tensile tests, as an index.

1) A strip-like cured material having a length of 70 mm and a width of 5 mm, is prepared as a test piece.

2) The test piece is in a state of being retained by chucks having a distance therebetween of 50 mm, and the test piece is pulled by a displacement amount (strain) X, in the first tensile test.

3) The chucks are returned to the initial position.

4) The second tensile test is performed, and a difference Y between the displacement amount (strain) in a position where a load is started to be applied (a load rising position) and X is recorded.

5) The stretch recovery rate is calculated according to Expression: Stretch Recovery Rate R=(Y/X)×100.

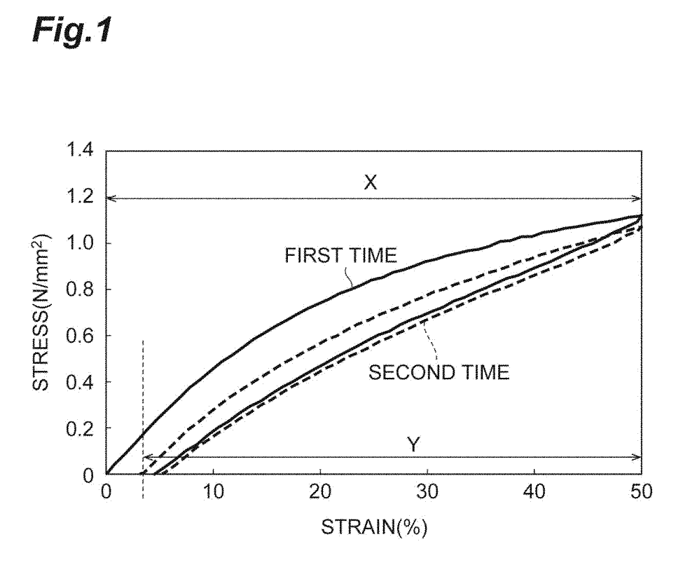

The tensile test is performed in an environment of 25° C. X can be set to a displacement amount of 25 mm (strain of 50%). For example, a microforce tester (Illinois Tool Works Inc, “Instron 5948”) can be used as a tester. FIG. 1 is an example of a stress-strain curve obtained from the tensile test for obtaining the stretch recovery properties. The thickness of the test piece for evaluating the stretch recovery properties, may be 100±10 μm.

The stretch recovery rate described above, may be greater than or equal to 80%, may be greater than or equal to 85%, or may be greater than or equal to 90%, from the viewpoint of resistance with respect to repeated use. The upper limit of the stretch recovery rate is not particularly limited, but may be 100%. The curable composition according to the embodiment described above, in general, is capable of easily forming the cured material having a stretch recovery rate of 80%.

The cured material (the stretchable resin layer) formed of the curable composition, may have the total light transmittance of greater than or equal to 80%, an yellowness index (YI) of less than or equal to 5.0, and a haze of less than or equal to 5.0%, from the viewpoint of the transparency. The total light transmittance, the YI, and the haze can be measured by using a spectral hazemeter (a spectral hazemeter “SH7000”, manufactured by NIPPON DENSHOKU INDUSTRIES CO., LID.). The total light transmittance may be greater than or equal to 85%, the YI may be less than or equal to 4.0, and the haze may be less than or equal to 4.0%. The total light transmittance may be greater than or equal to 90%, the YI may be less than or equal to 3.0, and the haze may be less than or equal to 3.0%.

The cured material (the stretchable resin layer) formed of the curable composition, for example, can be applied or used as a stretchable sealing resin layer configuring wearable appliances.

Semiconductor Device

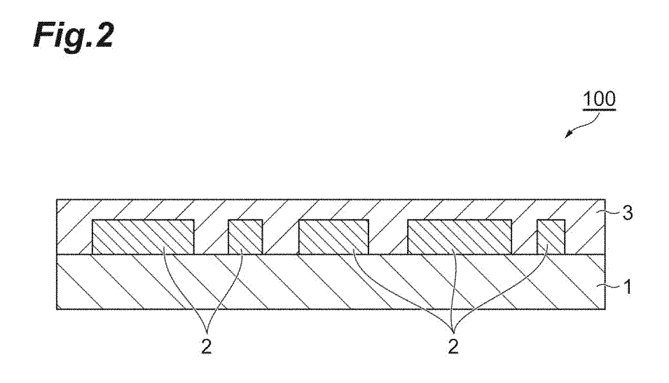

FIG. 2 is a sectional view schematically illustrating a semiconductor device according to an embodiment. A semiconductor device 100 according to this embodiment, includes a circuit board provided with a flexible substrate 1 having stretchability, a circuit component 2, and a stretchable resin layer 3. The flexible substrate 1 may be a stretchable resin layer. The circuit component 2 is mounted on the flexible substrate 1. The stretchable resin layer 3 can be a cured material (a cured film) formed from the curable composition according to the embodiment described above. The stretchable resin layer 3 is formed by curing the film-formed curable composition. The stretchable resin layer 3 seals the flexible substrate 1 and the circuit component 2, to protect the front surface of the circuit board.

A configuration material of the flexible substrate 1 may be selected according to the object. The configuration material of the flexible substrate 1 may be at least one kind selected from the group consisting of a polyimide resin, an acrylic resin, a silicone resin, a urethane resin, a bismaleimide resin, an epoxy resin, and a polyethylene glycol resin. Among them, the configuration material of the flexible substrate 1 may be at least one kind selected from the group consisting of a polyimide resin having a siloxane structure, an aliphatic ether structure, or a diene structure, an acrylic resin, a silicone resin, a urethane resin, a bismaleimide resin having a long-chain alkyl chain (for example, an alkyl chain having 1 to 20 carbon atoms), an epoxy resin, and a polyethylene glycol resin having a rotaxane structure, from the viewpoint of more excellent stretchability. Further, the configuration material of the flexible substrate 1 may be at least one kind selected from the group consisting of a polyimide resin having a siloxane structure, an aliphatic ether structure, or a diene structure, a silicone resin, a urethane resin, and a bismaleimide resin having a long-chain alkyl chain, from the viewpoint of more excellent stretchability. Only one kind selected from such resins or a combination of two or more kinds thereof can be used as the configuration material of the flexible substrate 1.

The circuit component 2, for example, is a mounting component such as a memory chip, a light emitting diode (LED), an RF tag (RFID), a temperature sensor, and an acceleration sensor. One kind of circuit component may be mounted on one flexible substrate 1, or two or more kinds of circuit components may be mounted on one flexible substrate 1 by being mixed. One or a plurality of circuit components 2 may be mounted on one flexible substrate 1.

Hereinafter, a manufacturing method of the semiconductor device according to this embodiment will be described.

Step 1: Mounting Step

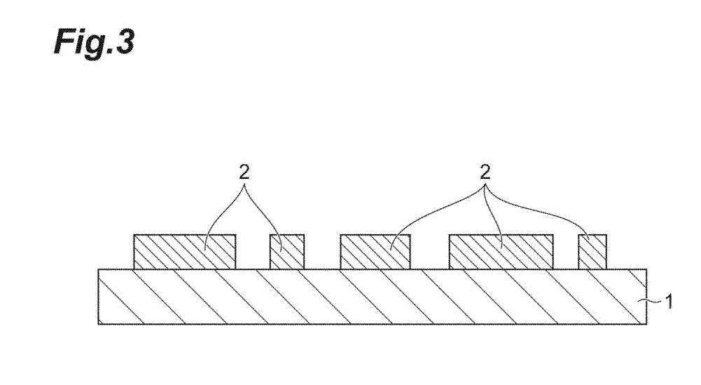

First, as illustrated in FIG. 3, the circuit component 2 is mounted on the flexible substrate 1.

Step 2: Sealing Step

Next, the flexible substrate 1 and the circuit component 2 are sealed with the curable composition as a sealing member. The flexible substrate 1 and the circuit component 2, for example, can be sealed by laminating the sealing member on the flexible substrate 1, by printing the sealing member on the flexible substrate 1, or by immersing the flexible substrate 1 in the sealing member and drying the flexible substrate 1. The sealing can be performed by a printing method, a dispensing method, a dipping method, or the like. Among them, a method that can be used in a Roll to Roll process, is capable of shortening a manufacture process.

Step 3: Curing Step

In the sealing step, the flexible substrate 1 and the circuit component 2 are sealed with the sealing member, and then, the sealing member (the curable composition) is cured, and thus, the stretchable resin layer 3 is formed, and a circuit board including the stretchable resin layer 3 can be obtained. Accordingly, the semiconductor device 100 as illustrated in FIG. 1, can be obtained. The curing can be thermal curing according to heating, or photocuring according to exposure.

Step 4: Cutting Step

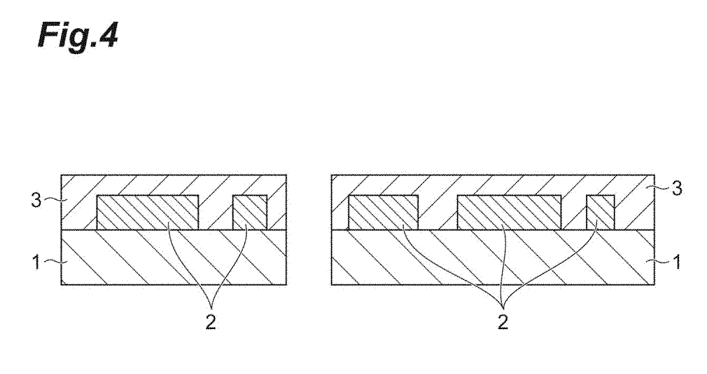

The manufacturing method of the semiconductor device, as necessary, for example, is capable of including a step of obtaining a plurality of semiconductor devices including the circuit component by cutting and separating the circuit board, as illustrated in FIG. 4. Accordingly, it is possible to manufacture the plurality of semiconductor devices at one time with a large area, and the manufacture process is easily reduced.

### EXAMPLES

Hereinafter, the present invention will be described in more detail by using examples. However, the present invention is not limited to the examples.

1. Preparation of Resin Varnish (Curable Composition)

### Example 1

30 parts by mass of a hydrogenated styrene isoprene copolymer (“SEPTON 2002”, manufactured by KURARAY CO., LTD.) as the component of (A), 30 parts by mass of isodecyl acrylate (“Sartomer SR395”, manufactured by Arkema Corporation) as the component of (B), 37 parts by mass of 4-tert-butylcyclohexanol acrylate (“Sartomer SR217”, manufactured by Arkema Corporation) as the component of (C), 2 parts by mass of tricyclodecane dimethanol diacrylate (“NK Ester A-DCP”, manufactured by Shin Nakamura Chemical Co., Ltd.) as the component of (D), and 1 part by mass of bis(2,4,6-trimethyl benzoyl) phenyl phosphine oxide (“Irgacure 819”, manufactured by BASF SE) as the component of (E), were mixed while being stirred in a flask of 500 ml at 60° C., and thus, a resin varnish was obtained.

### Examples 2 to 10 and Comparative Examples 1 to 3

A resin varnish was obtained by the same method as that in Example 1, according to a compounding ratio (parts by mass) shown in Table 1.

2. Evaluation

Elastic Modulus and Expansion Rate

The resin varnish of each of the examples and the comparative examples was applied onto a front surface of a PET film (“Purex A31”, manufactured by Teijin DuPont Films Co., Ltd., a thickness of 25 μm), the front surface being subjected to a release treatment, by using a knife coater (“SNC-350”, manufactured by Yasui Seiki Company, Ltd.). A coated film of the resin varnish was irradiated with an ultraviolet ray (a wavelength of 365 nm) in an exposure amount of 2000 mJ/cm², by an ultraviolet ray exposure machine (“ML-320FSAT”, manufactured by Mikasa Co., Ltd.), and thus, a cured film (a stretchable resin layer, a thickness of 100 μm) for physical properties evaluation was formed.

A strip-like test piece having a length of 40 mm and a width of 10 mm was cut out from the cured film. A tensile test of the test piece was performed in an environment of 25° C., by using Autograph (“EZ-S”, manufactured by SHIMADZU CORPORATION). From the obtained stress-strain curve, an elastic modulus and an expansion rate of the cured film were obtained. The tensile test was performed in a condition where a distance between chucks was 20 mm, and a tensile rate was 50 mm/min. The elastic modulus was obtained from a slope of the stress-strain curve in a range of a load of 0.5 N to 1.0 N. The expansion rate was obtained from strain (an elongation at break) at a point when the cured film fractured.

Stretch Recovery Rate

A strip-like test piece having a length of 70 mm and a width of 5 mm was cut out from the cured film for evaluation, described above. A recovery rate of the test piece was measured in an environment of 25° C., according to two times of tensile tests using a microforce tester (“Instron 5948”, Illinois Tool Works Inc). In the first tensile test, the test piece was pulled by the displacement amount (strain) X, and then, the chucks were returned to the initial position, and then, the second tensile test was performed. In the second tensile test, when a difference between the displacement amount (strain) in a position where a load was started to be applied (a load rising position) and X is set to Y, a stretch recovery rate R is a value calculated by Expression: R=(Y/X)×100. In this measurement, the initial length (the distance between the chucks) was 50 mm, and X was 25 mm (the strain of 50%).

Total Light Transmittance, YI, and Haze

A test piece having a length of 30 mm and a width of 30 mm was cut out from the cured film for evaluation, described above. The total light transmittance, the YI, and the haze of the test piece were measured in an environment of 25° C., by using a spectral hazemeter (“SH7000”, manufactured by NIPPON DENSHOKU INDUSTRIES CO., LTD.).

Evaluation of Adhesiveness

A resin varnish was applied onto a polyimide film having a thickness of 50 μm (“Kapton 100H”, manufactured by DU PONT-TORAY CO., LTD.), by using a knife coater (“SNC-350”, manufactured by Yasui Seiki Company, Ltd.). A coated film of the resin varnish was irradiated with an ultraviolet ray (a wavelength of 365 nm) in an exposure amount of 2000 mJ/cm², by an ultraviolet ray exposure machine (“ML-320FSAT”, manufactured by Mikasa Co., Ltd.), and thus, a cured film (a stretchable resin layer, a thickness of 100 μm) was formed on the polyimide film. A strip-like test piece having a length of 50 mm and a width of 10 mm was cut out from a laminate of the polyimide film and the cured film. The cured film side of the test piece was fixed to a copper plate by using an adhesive agent (“Cemedine Super X Gold”, manufactured by CEMEDINE CO., LTD.). The polyimide film was peeled off from the cured film fixed to the copper plate, at a rate of 50 mm/min, in a direction of an angle of 90 degrees with respect to the cured film, in an environment of 25° C., by using Autograph (“EZ-S”, manufactured by SHIMADZU CORPORATION). At this time, the adhesiveness was evaluated on the basis of the maximum value of a tensile stress per unit width (N/cm).

TABLE 1

| Item | | | Unit | Ex. 1 | Ex. 2 | Ex. 3 | Ex. 4 | Ex. 5 | Ex. 6 | Ex. 7 | Ex. 8 |
|---|---|---|---|---|---|---|---|---|---|---|---|
| Composition | (A) Elastomer | SEPTON 2002¹⁾ | Parts | 30 | — | 30 | 30 | 30 | 30 | 30 | 30 |
| | | Kraton MD6951²⁾ | by | — | 30 | — | — | — | — | — | — |
| | | KAYAFLEX | mass | — | — | — | — | — | — | — | — |
| | | BPAM-155³⁾ | | | | | | | | | |
| | (B) Monofunctional | SR395⁴⁾ | | 30 | 30 | 30 | 30 | 30 | — | — | 30 |
| | straight-chain alkyl | SR440⁵⁾ | | — | — | — | — | — | 30 | — | — |
| | (meth)acrylate | LA⁶⁾ | | — | — | — | — | — | — | 30 | — |
| | (C) Monofunctional | SR217⁷⁾ | | 37 | 37 | — | — | — | 37 | 37 | 37 |
| | (meth)acrylate having | SR420⁸⁾ | | — | — | 37 | — | — | — | — | — |
| | alicyclic group | FA-513AS⁹⁾ | | — | — | — | 37 | — | — | — | — |
| | | BLEMMER CHA¹⁰⁾ | | — | — | — | — | 37 | — | — | — |
| | (D) Difunctional or higher | A-DCP¹¹⁾ | | 2 | 2 | 2 | 2 | 2 | 2 | 2 | — |
| | compound having two or | CD406¹²⁾ | | — | — | — | — | — | — | — | 2 |
| | more ethylenically | FA-129AS¹³⁾ | | — | — | — | — | — | — | — | — |
| | unsaturated groups | | | | | | | | | | |
| | (E) Polymerization initiator | Irgacure 819¹⁴⁾ | | 1 | 1 | 1 | 1 | 1 | 1 | 1 | 1 |

| Mechanical properties | Elastic Modulus | MPa | 1.2 | 1.5 | 0.6 | 0.4 | 0.8 | 1 | 0.5 | 1 |
|---|---|---|---|---|---|---|---|---|---|---|
| | Expansion Rate | % | 230 | 260 | 270 | 310 | 290 | 240 | 400 | 250 |
| | Stretch Recovery Rate | % | 86 | 87 | 89 | 94 | 93 | 86 | 95 | 89 |
| | Adhesiveness | N/cm | 9.3 | 7.6 | 4.5 | 3.1 | 3.8 | 8.5 | 4.2 | 6.5 |
| Optical properties | Total Light Transmittance | % | 88 | 87 | 88 | 92 | 92 | 88 | 85 | 87 |
| | YI | — | 2.1 | 3.4 | 2.5 | 0.6 | 1.8 | 2.3 | 4.1 | 2.3 |
| | Haze | — | 3.4 | 5.1 | 3.6 | 1.1 | 2.7 | 3.5 | 5.5 | 3.5 |

| | | | | | | Comp. | Comp. | Comp. |
|---|---|---|---|---|---|---|---|---|
| Item | | | Unit | Ex. 9 | Ex. 10 | Ex. 1 | Ex. 2 | Ex. 3 |
| Composition | (A) Elastomer | SEPTON 2002¹⁾ | Parts | 30 | 30 | 30 | 30 | — |
| | | Kraton MD6951²⁾ | by | — | — | — | — | — |
| | | KAYAFLEX | mass | — | — | — | — | 30 |
| | | BPAM-155³⁾ | | | | | | |
| | (B) Monofunctional | SR395⁴⁾ | | 30 | 30 | 67 | — | 30 |
| | straight-chain alkyl | SR440⁵⁾ | | — | — | — | — | — |
| | (meth)acrylate | LA⁶⁾ | | — | — | — | — | — |
| | (C) Monofunctional | SR217⁷⁾ | | 37 | 25 | — | 55 | 25 |
| | (meth)acrylate having | SR420⁸⁾ | | — | — | — | — | — |
| | alicyclic group | FA-513AS⁹⁾ | | — | 12 | — | 12 | 12 |
| | | BLEMMER CHA¹⁰⁾ | | — | — | — | — | — |
| | (D) Difunctional or higher | A-DCP¹¹⁾ | | — | 2 | 2 | 2 | 2 |
| | compound having two or | CD406¹²⁾ | | — | — | — | — | — |
| | more ethylenically | FA-129AS¹³⁾ | | 2 | — | — | — | — |
| | unsaturated groups | | | | | | | |
| | (E) Polymerization initiator | Irgacure 819¹⁴⁾ | | 1 | 1 | 1 | 1 | 1 |

| Mechanical properties | Elastic Modulus | MPa | 0.8 | 0.5 | 0.2 | 25 | 310 |
|---|---|---|---|---|---|---|---|
| | Expansion Rate | % | 280 | 290 | 420 | 110 | 72 |
| | Stretch Recovery Rate | % | 90 | 93 | 96 | 76 | 51 |
| | Adhesiveness | N/cm | 4.5 | 3.9 | 0.02 | 23 | 30 |
| Optical properties | Total Light Transmittance | % | 87 | 91 | 86 | 89 | 74 |

| | | | | | | |
|---|---|---|---|---|---|---|
| YI | — | 2.6 | 0.8 | 3.8 | 1.8 | 12.5 |
| Haze | — | 3.8 | 1.4 | 4.2 | 2.5 | 34.6 |

(A) Elastomer

1) SEPTON 2002 (a hydrogenated styrene isoprene copolymer, manufactured by KURARAY CO., LID., Weight Average Molecular Weight: 55,000)

2) Kraton MD6951 (a hydrogenated styrene butadiene copolymer, manufactured by KRATON CORPORATION, Weight Average Molecular Weight: 60,000)

3) KAYAFLEX BPAM-155 (rubber modified polyamide, manufactured by Nippon Kayaku Co., Ltd., Weight Average Molecular Weight: 31,000)

(B) Monofunctional Straight-Chain Alkyl (Meth)Acrylate

4) SR395 (isodecyl acrylate, “Sartomer SR395”, manufactured by Arkema Corporation)

5) SR440 (isooctyl acrylate, “Sartomer SR440”, manufactured by Arkema Corporation)

6) LA (lauryl acrylate, manufactured by Osaka Organic Chemical Industry Co., Ltd.)

(C) Monofunctional (Meth)Acrylate Having Alicyclic Group

7) SR217 (4-tert-butyl cyclohexanol acrylate, “Sartomer SR217”, manufactured by Arkema Corporation)

8) SR420 (3,3,5-trimethyl cyclohexanol acrylate (“Sartomer SR420”, manufactured by Arkema Corporation)

9) FA-513AS (dicyclopentanyl acrylate, “FANCRYL FA-513AS”, manufactured by Hitachi Chemical Company, Ltd.)

10) BLEMMER CHA (cyclohexyl acrylate, manufactured by NOF CORPORATION)

(D) Difunctional or Higher Compound

11) A-DCP (tricyclodecane dimethanol diacrylate, “NK Ester A-DCP”, manufactured by Shin Nakamura Chemical Co., Ltd.)

12) CD406 (cyclohexane dimethanol diacrylate, “Sartomer CD406”, manufactured by Arkema Corporation)

13) FA-129AS (nonanediol diacrylate (“FANCRYL FA-129AS”, manufactured by Hitachi Chemical Company, Ltd.)

(E) Polymerization Initiator

14) Irgacure 819 (bis(2,4,6-trimethyl benzoyl) phenyl phosphine oxide, manufactured by BASF Japan Co., Ltd.)

Table 1 shows an evaluation result. The cured film (the stretchable resin layer) forming from the resin varnish (the curable composition) of each of the examples, had sufficiently excellent stretchability and adhesiveness. On the other hand, the cured film formed from the resin varnish of Comparative Example 1, not containing the component of (C), had low adhesiveness. The cured film formed from the resin varnish of Comparative Example 2, not containing the component of (B), had low stretchability and a low expansion rate. The cured film formed from the resin varnish of Comparative Example 3, containing rubber modified polyimide as an elastomer, had low stretchability, and was not sufficient for optical properties.

### INDUSTRIAL APPLICABILITY

The cured material (the stretchable resin layer) formed from the curable composition of the present invention, has excellent stretchability and adhesiveness, and thus, for example, can be applied and used as a sealing layer for protecting a circuit board of wearable appliances. The stretchable resin layer formed of the curable composition of the present invention, is also capable of having excellent performance in long-term reliability in an environment of high humidity.

### REFERENCE SIGNS LIST

1: flexible substrate, 2: circuit component, 3: stretchable resin layer, 100: semiconductor device.

1. A curable composition for forming a stretchable resin layer, comprising:
(A) an elastomer having a polystyrene chain;
(B) monofunctional straight-chain alkyl (meth)acrylate;
(C) monofunctional (meth)acrylate having an alicyclic group;
(D) a difunctional or higher compound having two or more ethylenically unsaturated groups; and
(E) a polymerization initiator.

2. The curable composition for forming a stretchable resin layer according to claim 1,
wherein (A) the elastomer having a polystyrene chain is a copolymer further having a hydrogenated polydiene chain.

3. The curable composition for forming a stretchable resin layer according to claim 1,
wherein (E) the polymerization initiator is a photoradical polymerization initiator.

4. The curable composition for forming a stretchable resin layer according to claim 1,
wherein the number of carbon atoms of a straight-chain alkyl group of (B) the monofunctional straight-chain alkyl (meth)acrylate, is less than or equal to 12.

5. The curable composition for forming a stretchable resin layer according to claim 1,
wherein a content of (D) the difunctional or higher compound having two or more ethylenically unsaturated groups, is 0.3 mass % to 20 mass %, with respect to the total amount of a component of (A), a component of (B), a component of (C), and a component of (D).

6. A stretchable resin layer that is a cured material of the curable composition for forming a stretchable resin layer according to claim 1.

7. A semiconductor device, comprising:
the stretchable resin layer according to claim 6.
